(19) United States
(12) Patent Application Publication
(10) Pub. No.: US 2019/0214358 A1
(43) Pub. Date: Jul. 11, 2019

(54) SEMICONDUCTOR DEVICE, SEMICONDUCTOR PACKAGE INCLUDING SEMICONDUCTOR DEVICE, AND METHOD OF MANUFACTURING SEMICONDUCTOR DEVICE

(71) Applicant: Samsung Electronics Co., Ltd., Suwon-si (KR)

(72) Inventors: Sang Su HA, Suwon-si (KR); Gun Rae KIM, Seongnam-si (KR); Cheol Hyeon PARK, Seongnam-si (KR); In Hak BAICK, Seoul (KR); Sang Chul SHIN, Seongnam-si (KR)

(21) Appl. No.: 16/038,334

(22) Filed: Jul. 18, 2018

(30) Foreign Application Priority Data
Jan. 11, 2018 (KR) 10-2018-0003634

(51) Int. Cl. H01L 23/00

(52) U.S. Cl. CPC H01L 24/17; H01L 24/11; H01L 24/08; H01L 24/81; H01L 23/562; H01L 2924/01078; H01L 2924/01029; H01L 2924/01079; H01L 2924/01013; H01L 2924/01028; H01L 2924/01074; H01L 24/32

(57) ABSTRACT

A semiconductor device including a high-reliability bump structure including a pillar structure is provided. The semiconductor device includes a substrate, a connection pad on the substrate, and a bump structure on the connection pad, wherein the bump structure includes a pillar structure having a side wall and an upper surface, a metal protection film including a first portion extending along the side wall of the pillar structure and a second portion extending along the upper surface of the pillar structure, and a solder layer on the second portion of the metal protection film.

This application claims priority from Korean Patent Application No. 10-2018-0003634, filed on Jan. 11, 2018, in the Korean Intellectual Property Office, the disclosure of which is incorporated herein by reference in its entirety.

### BACKGROUND

### 1. Field

The disclosure relates to a semiconductor device, a semiconductor package including the semiconductor device, and a method of manufacturing the semiconductor device.

### 2. Description of the Related Art

In the production of various electronic components, techniques for mounting electronic components such as semiconductor chips using solder bumps or producing semiconductor laminated packages are widely used.

Particularly, in order to miniaturize, lighten and improve electronic devices in accordance with the rapid development speed of electronic products, studies for forming fine and precise bumps have been actively made in the development of microelectronic packaging techniques and the like. In conventional bumps, methods of arranging bumps using solder have been generally used. Such solder bumps are characterized in that the pitch between the solder bumps decreases, thereby increasing a risk of short circuit between the solder bumps.

Therefore, there is an issue related to the fine pitch, which can impose a limit to the miniaturization of a semiconductor package. In order to address this issue, there are used methods of further reducing the pitch between bumps using filler bumps provided thereon with solder.

### SUMMARY

In one aspect, the disclosure is directed to providing a semiconductor device including a high-reliability bump structure including a pillar structure.

In another aspect, the disclosure is directed to providing a semiconductor package including a high-reliability bump structure including a pillar structure.

In still another aspect, the disclosure is directed to providing a method of manufacturing a semiconductor device including a high-reliability bump structure including a pillar structure.

According to certain embodiments, the disclosure is directed to a semiconductor device, comprising: a substrate; a connection pad on the substrate; and a bump structure on the connection pad, wherein the bump structure includes: a pillar structure having a side wall and an upper surface, a metal protection film including a first portion extending along the side wall of the pillar structure and a second portion extending along the upper surface of the pillar structure, and a solder layer on the second portion of the metal protection film.

According to certain embodiments, the disclosure is directed to a semiconductor device, comprising: a substrate; a connection pad on the substrate; and a bump structure on the connection pad, wherein the bump structure includes a pillar structure having a side wall and an upper surface, a metal protection film formed of a metal and extending along the side wall of the pillar structure, and a solder layer on the upper surface of the pillar structure, wherein the solder layer includes a first region defined along the upper surface of the pillar structure and a second region on the first region, and both the first region and the second region include the metal contained in the metal protection film, and wherein a concentration of the metal contained in the metal protection film in the first region of the solder layer is a first concentration, and a concentration of the metal contained in the metal protection film in the second region of the solder layer is a second concentration lower than the first concentration.

According to certain embodiments, the disclosure is directed to a semiconductor device, comprising: a substrate; a connection pad on the substrate; a passivation film including a pad trench exposing a part of the connection pad on the substrate; a lower metal film extending along a side wall and bottom surface of the pad trench; and a bump structure on the lower metal film, wherein the bump structure includes: a pillar structure containing copper (Cu), a metal protection film extending along a side wall of the lower metal film, a side wall of the pillar structure, and an upper surface of the pillar structure, the metal protection film containing nickel, and a solder layer on the metal protection film.

According to certain embodiments, the disclosure is directed to a semiconductor package, comprising: a support substrate; a first semiconductor chip connected to the support substrate and including a first connection pad; and a first bump structure connected to the first connection pad and disposed between the first semiconductor chip and the support substrate, wherein the first bump structure includes: a first pillar structure including a side wall and an upper surface, a first metal protection film including a first portion extending along the side wall of the first pillar structure and a second portion extending along the upper surface of the first pillar structure, and a first solder layer on the second portion of the first metal protection film.

According to certain embodiments, the disclosure is directed to a method of manufacturing a semiconductor device, comprising: forming a connection pad on a substrate; forming a mask film including an opening overlapping the connection pad on the substrate; forming a pillar structure connected to the connection pad in the opening; forming a metal protection film along a side wall and upper surface of the pillar structure;

and forming a solder layer on the metal protection film on the upper surface of the pillar structure.

### BRIEF DESCRIPTION OF THE DRAWINGS

The above and other aspects and features of the invention will become more apparent by describing in detail exemplary embodiments thereof with reference to the attached drawings, in which:

FIG. 1 is an exemplary view illustrating a semiconductor device, according to an example embodiment;

FIG. 2 is a cross-sectional view taken along the line A-A in FIG. 1;

FIG. 3 is an enlarged view of the portion P in FIG. 2;

FIG. 4 is a view for explaining a semiconductor device, according to an example embodiment;

FIG. 5 is a view for explaining a semiconductor device, according to another example embodiment;

FIG. 6 is a view for explaining a semiconductor device, according to still another example embodiment;

FIG. 7 is a view for explaining a semiconductor device, according to still another example embodiment;

FIG. 8 is a view for explaining a semiconductor package, according to an example embodiment;

FIG. 9 is a view for explaining a semiconductor package, according to another example embodiment;

FIG. 10 is an enlarged view of the portion Q in FIG. 9;

FIG. 11 is a view for explaining a semiconductor package, according to still another example embodiment;

FIG. 12 is a view for explaining a semiconductor package, according to still another example embodiment; and

FIGS. 13 to 24 are intermediate views for explaining a method of a manufacturing a semiconductor device, according to an example embodiment.

### DETAILED DESCRIPTION

Hereinafter, embodiments will be described with reference to the attached drawings.

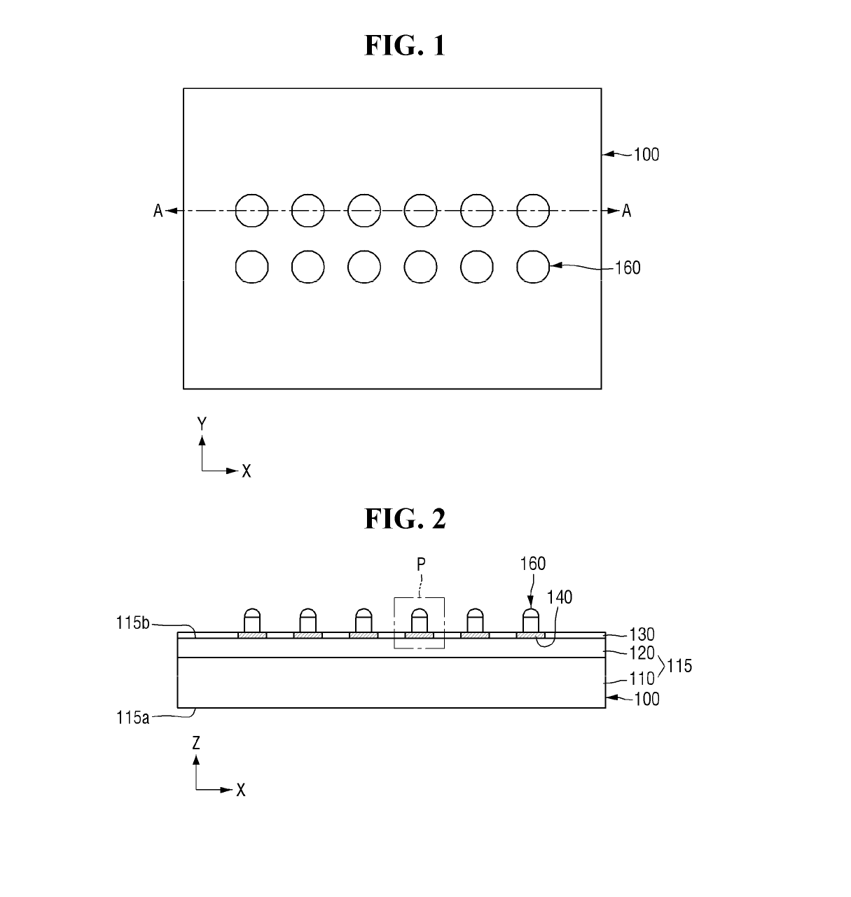

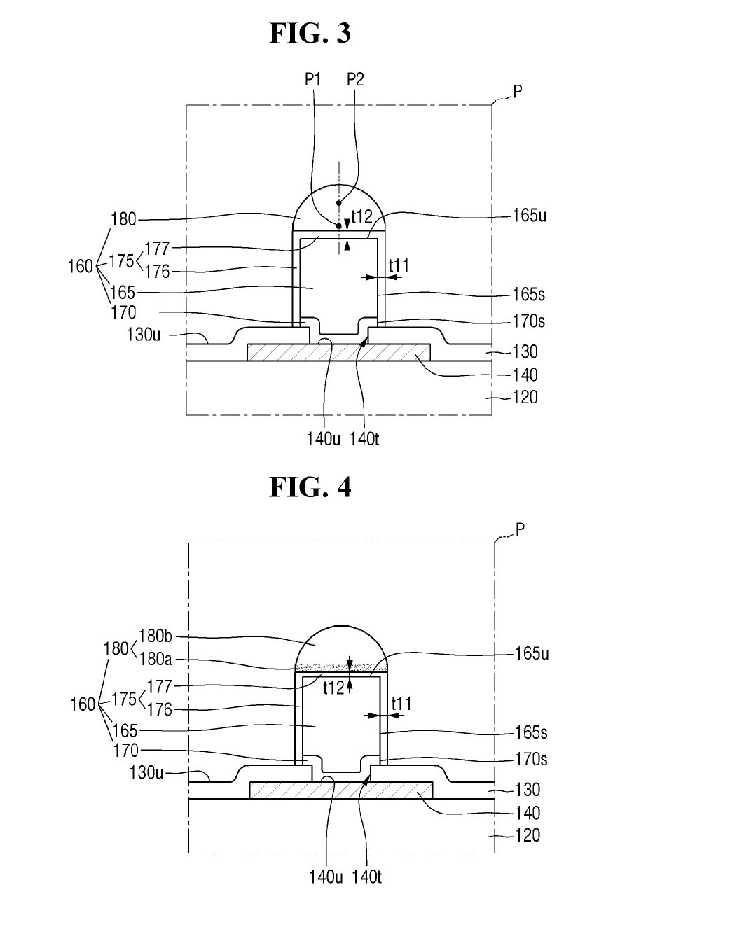

FIG. 1 is an exemplary view illustrating a semiconductor device according to an embodiment. FIG. 2 is a cross-sectional view taken along the line A-A in FIG. 1. FIG. 3 is an enlarged view of portion P in FIG. 2.

Referring to FIGS. 1 to 3, a semiconductor device according to an embodiment may include a first semiconductor chip 100 and first bump structures 160.

The first semiconductor chip 100 may be, for example, a logic semiconductor chip or a memory semiconductor chip. When the first semiconductor chip 100 is a logic semiconductor chip, the first semiconductor chip 100 may be designed in various ways in consideration of operations to be performed. The first semiconductor chip 100 may be, for example, a processor unit. The first semiconductor chip 100 may be, for example, a micro-processor unit (MPU) or a graphic processor unit (GPU), but is not limited thereto.

When the first semiconductor chip 100 is a memory semiconductor chip, the first semiconductor chip 100 may be a volatile memory semiconductor chip such as a dynamic random access memory (DRAM) or a static random access memory (SRAM), or may be a nonvolatile memory such as a flash memory, a phase-change random access memory (PRAM), a magnetoresistive random access memory (MRAM), a ferroelectric random access memory (FeRAM), or a resistive random access memory (RRAM).

The first semiconductor chip 100 may include a first chip substrate 115, a first passivation film 130, and a first connection pad 140.

The first chip substrate 115 may include a first surface 115a and a second surface 115b, facing away from each other. The first chip substrate 115 may include a first semiconductor substrate 110 and a first semiconductor device layer 120. The first surface 115a of the first chip substrate 115 may be defined by the first semiconductor substrate 110, and the second surface 115b of the first chip substrate 115 may be defined by the first semiconductor device layer 120. For example, the first surface 115a may be an outside surface of the first semiconductor substrate 110, and the second surface 115b may be an outside surface of the first semiconductor device layer 120.

The first semiconductor substrate 110 may be a bulk silicon substrate or a silicon-on-insulator (SOI) substrate. In other embodiments, the first semiconductor substrate 110 may be a silicon substrate, or may be a substrate containing silicon germanium, silicon germanium on insulator (SGOI), indium antimonide, a lead tellurium compound, indium arsenide, indium phosphide, gallium arsenide, or gallium antimonide, but the present disclosure is not limited thereto.

The first semiconductor device layer 120 may include various kinds of a plurality of individual devices and an interlayer insulating film. The plurality of individual devices may include various microelectronic devices, for example, a metal-oxide-semiconductor field effect transistor (MOSFET) such as a complementary metal-insulator-semiconductor (CMOS) transistor, a system LSI (large scale integration), a flash memory, DRAM, SRAM, EEPROM, PRAM, MRAM, PRRAM, an image sensor such as a CMOS image sensor (CIS), a micro-electro-mechanical system, an active device, and a passive device. The plurality of individual devices may be electrically connected to the conductive regions formed in the first semiconductor substrate 110. The first semiconductor device layer 120 may include a conductive wiring or conductive plug electrically connecting at least two of the plurality of individual devices or electrically connecting the plurality of individual devices and the conductive regions of the first semiconductor substrate 110. Further, the plurality of individual devices may be electrically separated from other neighboring devices by insulating films. The first connection pad 140 may be disposed on the second surface 115b of the first chip substrate 115. The first connection pad 140 may be formed on the first semiconductor device layer 120. The first connection pad 140 may be electrically connected to various ones of the plurality of individual devices formed in the first semiconductor device layer 120.

The first connection pad 140 may contain at least one of aluminum (Al), copper (Cu), nickel (Ni), tungsten (W), platinum (Pt), and gold (Au).

The first passivation film 130 may be disposed on the second surface 115b of the first chip substrate 115. The first passivation film 130 may be disposed on the first connection pad 140.

The first passivation film 130 may expose a part of the first connection pad 140. For example, the first passivation film 130 may expose a part of the upper surface 140u of the first connection pad 140. The first passivation film 130 may cover at least a part of the first connection pad 140. For example, the first passivation film 130 may cover side surfaces and at least part of the upper surface 140u of the first connection pad 140.

The first passivation film 130 may include a first pad trench 140t exposing a part of the first connection pad 140. The first pad trench 140t may include a side wall defined by the first passivation film 130 and a bottom surface defined by the upper surface 140u of the first connection pad 140. The side wall of the first pad trench 140t may be perpendicular to the upper surface 140u of the first connection pad 140.

The first passivation film 130 may include at least one of an inorganic material layer and an organic material layer.

The first bump structure 160 may be disposed on the first connection pad 140. The first bump structure 160 may be connected to the first connection pad 140. For example, the first bump structure 160 may be electrically connected to and in contact with the first connection pad 140. It will be understood that the term “contact,” as used herein, refers to a connection contact (i.e., touching) unless the context indicates otherwise.

The first bump structure 160 may be disposed in the first pad trench 140t. The first bump structure 160 may cover a part of the first passivation film 130. For example, the first bump structure 160 may cover a portion of the first passivation layer 130 that covers the first connection pad 140. The first bump structure 160 may include a portion extending along a part of the upper surface 130u of the first passivation film. The width of the first bump structure 160 may be greater than the width of the upper surface 140u of the first connection pad 140 exposed by the first pad trench 140t. The width of the first bump structure 160 may be smaller than the width of the first connection pad 140.

The first bump structure 160 may include a first pillar structure 165, a first lower metal film 170, a first metal protection film 175, and a first solder layer 180.

The first pillar structure 165 may be disposed on the first connection pad 140. The first pillar structure 165 may cover a part of the first passivation film 130. An upper portion of the first pillar structure 165 may have a cylindrical shape.

The first pillar structure 165 may include an upper surface 165u and a side wall 165s extending in a third direction Z. The upper surface 165u may be parallel to the upper surface 140u of the first connection pad 140, and the side wall 165s may be perpendicular to the upper surface 165u.

The first pillar structure 165 may contain, for example, copper (Cu), a copper alloy, nickel (Ni), a nickel alloy, palladium (Pd), platinum (Pt), gold (Au), cobalt, or a combination thereof. In the following description, it is assumed that the first pillar structure 165 contains copper (Cu) or a copper alloy.

The first lower metal film 170 may be disposed between the first connection pad 140 and the first pillar structure 165. The first lower metal film 170 may extend along the side wall and bottom surface of the first pad trench 140t. A part of the first lower metal film 170 may extend along the upper surface 130u of the first passivation film 130. The first lower metal film 170 may be conformally formed on the first passivation film 130 and the first connection pad 140 to have a step shape.

The first lower metal film 170 may be a seed layer for forming the first pillar structure 165, an adhesive layer, or a barrier layer. The first lower metal film 170 may contain chromium (Cr), tungsten (W), titanium (Ti), copper (Cu), nickel (Ni), aluminum (Al), palladium (Pd), gold (Au), or a combination thereof.

The first lower metal film 170 may be one metal layer, or may be a laminate structure including a plurality of metal layers. For example, the first lower metal film 170 may include a first metal layer, a second metal layer, and/or a third metal layer, which are sequentially laminated on the first connection pad 140.

The first metal layer may function as an adhesive layer for stably attaching the first bump structure 160 formed on the first metal layer to the first connection pad 140 and/or the first passivation film 130. For example, the first metal layer may contain at least one of titanium (Ti), titanium-tungsten (Ti—W), chromium (Cr), and aluminum (Al), but the present disclosure is not limited thereto. The second metal layer may function as a barrier layer for preventing the diffusion of the metal material contained in the first connection pad 140 into the first chip substrate 115. The second metal layer may contain at least one of copper (Cu), nickel (Ni), chrome-copper (Cr—Cu), and nickel-vanadium (Ni—V), but the present disclosure is not limited thereto. The third metal layer may function as a seed layer for forming the first bump structure 160 or as a wetting layer for improving the wetting characteristics of the solder layer. The third metal layer may contain at least one of nickel (Ni), copper (Cu), and aluminum (Al), but the present disclosure is not limited thereto.

The first metal protection film 175 may be disposed on the first pillar structure 165. The first metal protection film 175 may extend along the side wall 165s of the first pillar structure and the upper surface 165u of the first pillar structure.

The first metal protection film 175 may include a first portion 176 and a second portion 177. The first portion 176 of the first metal protection film 175 may extend along the side wall 165s of the first pillar structure 165. The second portion 177 of the first metal protection film 175 may extend along the upper surface 165u of the first pillar structure 165.

The first portion 176 of the first metal protection film 175 may extend along the entire side wall 165s of the first pillar structure 165. The first portion 176 of the first metal protection film 175 may extend along the side wall 170s of the first lower metal film 170. The side wall 165s of the first pillar structure 165 and the side wall 170s of the first lower metal film 170 may be aligned with one another in the third direction Z.

The first portion 176 of the first metal protection film 175 may cover the entire side wall 165s of the first pillar structure 165 and the entire side wall 170s of the first lower metal film 170. The first portion 176 of the first metal protection film 175 may be in contact with the first passivation film 130. For example, a bottom surface of the first portion 176 may be in contact with the upper surface 130u of the first passivation film 130.

The first metal protection film 175 may contain a material different from that of the first pillar structure 165. The first metal protection film 175 may contain a material capable of preventing the oxidation of the first pillar structure 165. The first metal protection film 175 may contain a material capable of inhibiting the formation of an intermetallic compound (IMC) between the first pillar structure 165 and the first solder layer 180.

The first metal protection film 175 may contain at least one of nickel (Ni), cobalt (Co), platinum (Pt), silver (Ag), gold (Au), and aluminum (Al). In the following description, it is assumed that the first metal protection film 175 contains nickel (Ni). The first metal protection film 175 may contain pure nickel (Ni). The first metal protection film 175 may contain nickel (Ni) containing a small amount of phosphorus (P) or boron (B) introduced during a plating process.

In the semiconductor device according to some embodiments, the thickness t11 of the first portion 176 of the first metal protection film 175 is substantially equal to the thickness t12 of the second portion 177 of the first metal protection film 175. Items described as “substantially the same” or “substantially equal” may be exactly the same or equal, or may be the same or equal within acceptable variations that may occur, for example, due to manufacturing processes.

The first metal protection film 175 may be formed, for example, through an electroless plating process. When the electroless plating process is used, the first metal protection film 175 may have thickness uniformity.

The first solder layer 180 may be disposed on the first metal protection film 175. The first solder layer 180 may be disposed on the second portion 177 of the first metal protection film 175.

The first solder layer 180 may have, for example, a spherical or ball shape. When viewed from a top view, the first solder layer 180 may have a diameter that is the same as a diameter of the first pillar structure 165 and/or the second portion 177 of the first metal protection film 175. The first solder layer 180 may contain at least one of tin (Sn), indium (In), bismuth (Bi), antimony (Sb), copper (Cu), silver (Ag), zinc (Zn), lead (Pb), and/or an alloy thereof. For example, the first solder layer 180 may contain at least one of Sn, Sn—Pb, Sn—Ag, Sn—Au, Sn—Cu, Sn—Sn—Ag—Zn, Sn—Cu—Bi, Sn—Cu—Zn, and Sn—Bi—Zn.

When the first metal protection film 175 includes a nickel film, the concentration of nickel may decrease at locations in the first solder layer 180 that are further away from the second portion 177 of the first metal protection film 175, and increase at locations in the first solder layer 180 that are closer to the second portion 177 of the first metal protection film 175. For example, at the first point P1 located near the boundary of the second portion 177 of the first metal protection film 175 and the first solder layer 180, the concentration of nickel in the first solder layer 180 may be a first concentration. At the second point P2 spaced apart from the second portion 177 of the first metal protection film 175, compared to the first point P1, the concentration of nickel in the first solder layer 180 may be a second concentration lower than the first concentration.

In other words, the concentration of the metal contained in the first metal protection film 175 at the first point P1 may be higher than the concentration of the metal contained in the first metal protection film 175 at the second point P2.

The metal contained in the first metal protection film 175 may penetrate into the first solder layer 180 in the process of reflowing the first solder layer 180. In this case, the concentration of the metal contained in the first metal protection film 175 at the first point P1 may be higher than the concentration of the metal contained in the first metal protection film 175 at the second point P2. However, the degree of penetration of the metal contained in the first metal protection film 175 into the first solder layer 180 may vary depending on the phase diagram of the metal between the first metal protection film 175 and the first solder layer 180.

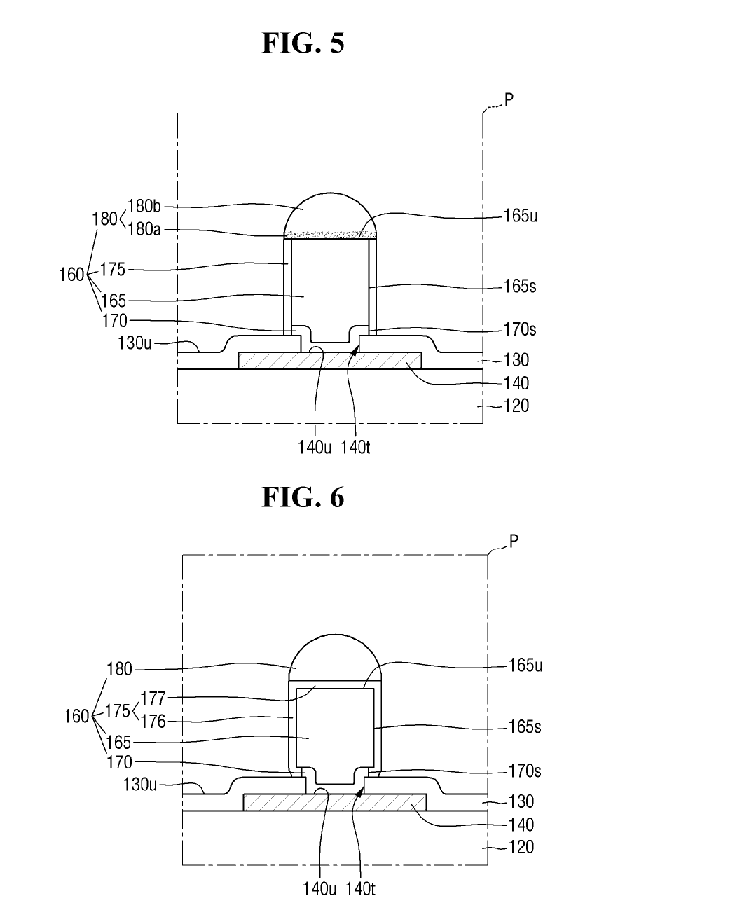

Contents thereof will be again described with reference to FIGS. 4 and 5.

Although it is shown in FIG. 1 that the first bump structures 160 are arranged at the central portion, the present disclosure is not limited thereto. Further, although it is shown in FIG. 1 that six first bump structures 160 are arranged in the first direction X and two rows are disposed in the second direction Y, this is only for convenience of description, and the present disclosure is not limited thereto.

FIG. 3 shows the shape of the first bump structure 160 taken along the first direction X of FIG. 1. However, the shape of the first bump structure 160 taken along the second direction Y of FIG. 1 may also be similar to that shown in FIG. 3.

The first metal protection film 175 is formed on the side wall 165s of the first pillar structure 165 and the upper surface 165u of the first pillar structure 165, thereby improving the reliability of the first bump structure 160 and the reliability of the semiconductor device.

Further, although it is shown that the first bump structure 160 includes the first lower metal film 170, the present disclosure is not limited thereto. In some cases, the first bump structure 160 may not include the first lower metal film 170.

FIG. 4 is a view for explaining a semiconductor device according to an example embodiment. For convenience of explanation, differences from those described with reference to FIGS. 1 to 3 will be mainly described. For reference, FIG. 4 is an enlarged view of the portion P in FIG. 2.

Referring to FIG. 4, in the semiconductor device according to an embodiment, the thickness t11 of the first portion 176 of the first metal protection film 175 is different from the thickness t12 of the second portion 177 of the first metal protection film 175.

For example, the thickness t11 of the first portion 176 of the first metal protection film 175 is greater than the thickness t12 of the second portion 177 of the first metal protection film 175. In the process of reflowing the first solder layer 180, a part of the first metal protection film 175 on the upper surface 165u of the first pillar structure 165 may enter the first solder layer 180.

The first solder layer 180 may include a first region 180a and a second region 180b on the first region 180a.

The first region 180a of the first solder layer 180 may be formed at the boundary with the first metal protection film 175. The first region 180a of the first solder layer 180 may be defined along the upper surface 165u of the first pillar structure 165. The first region 180a of the first solder layer 180 may be defined along the second portion 177 of the first metal protection film 175. For example, the first region 180a may be nearer to and above the upper surface 165u of the first pillar structure 165 and the second portion 177 of the first metal protection film 175, relative to the second region 180b of the first solder layer 180.

In the first region 180a of the first solder layer 180, the concentration of the metal contained in the first metal protection film 175 may be a first concentration. In the second region 180b of the first solder layer 180, the concentration of the metal contained in the first metal protection film 175 may be a second concentration lower than the first concentration. In some embodiments, the first concentration of the metal at locations in the first region 180a may be greater than the second concentration of the metal at locations in the second region 180b. For example, the first concentration of the metal contained in the first region 180a may gradually decrease at distances further away from the first metal protection film 175, and the second concentration of the metal in the second region 180b may gradually decrease at distances further away from the first metal protection film 175 and, correspondingly, at distances further away from the first region 180a.

When the first metal protection film 175 includes a nickel film, the concentration of nickel may decrease at locations in the first solder layer 180 that are further away from the second portion 177 of the first metal protection film 175, and increase at locations in the first solder layer 180 that are closer to the second portion 177 of the first metal protection film 175. For example, the concentration of nickel in the first region 180a of the first solder layer 180 is higher than the concentration of nickel in the second region 180b of the first solder layer 180. In the process of reflowing the first solder layer 180, the nickel contained in the first metal protection film 175 may not penetrate into the second region 180b of the first solder layer 180. Thus, the concentration of nickel in the first region 180a of the first solder layer 180 may be different from the concentration of nickel in the second region 180b of the first solder layer 180.

The first region 180a of the first solder layer 180, the boundary of which is defined by the metal contained in the first metal protection film 175 penetrating into the first solder layer 180, may be a solid solution region. When the first metal protection film 175 includes a nickel film, the first region 180a of the first solder layer 180 may be a solid solution region containing nickel.

In the vicinity of the boundary with the first metal protection film 175, the first solder layer 180 may include a solid solution region containing the metal contained in the first metal protection film 175. For example, in the region of the first solder layer 180 adjacent to the boundary between the first solder layer 180 and the first metal protection film 175, the first solder layer 180 may include a solid solution region containing the metal contained in the first metal protection film 175.

FIG. 5 is a view for explaining a semiconductor device according to another example embodiment. For convenience of explanation, differences from those described with reference to FIG. 4 will be mainly described. For reference, FIG. 5 is an enlarged view of the portion P in FIG. 2.

Referring to FIG. 5, in the semiconductor device according to another embodiment, the first metal protection film 175 may extend along the side wall 165s of the first pillar structure 165. However, the first metal protection film 175 may not extend along the upper surface 165u of the first pillar structure 165.

In the embodiment of FIG. 5, in the process of reflowing the first solder layer 180, the entire first metal protection film 175 formed on the upper surface 165u of the first pillar structure 165 may enter the first solder layer 180, forming the first region 180a and the second region 180b. In this embodiment, the first solder layer 180 may be in contact with the upper surface 165u of the first pillar structure 165.

FIG. 6 is a view for explaining a semiconductor device according to still another example embodiment. For convenience of explanation, differences from those described with reference to FIGS. 1 to 3 will be mainly described. For reference, FIG. 6 is an enlarged view of the portion P in FIG. 2.

Referring to FIG. 6, in the semiconductor device according to still another embodiment, the first lower metal film 170 may be undercut to the bottom of the first pillar structure 165. For example, the first lower metal film 170 may be formed under an outer are of the bottom surface of first pillar structure 165.

The side wall 170s of the first lower metal film 170 may be nearer to the side wall of the first pad trench 140t than the side wall 165s of the first pillar structure 165. The side wall 170s may be perpendicular to the upper surface 140u of the first connection pad 140, and parallel to the side wall of the first pad trench 140t and the side wall 165s of the first pillar structure 165. A distance between two opposing locations of the side wall 170s may be greater than a distance between two opposing locations of the side wall of the first pad trench 140t and smaller than a distance between two opposing locations of the side wall 165s of the first pillar structure 165.

The first metal protection film 175 is formed along the side wall 170s of the undercut first lower metal film 170, thereby preventing the deterioration of reliability of the semiconductor device including the first bump structure 160.

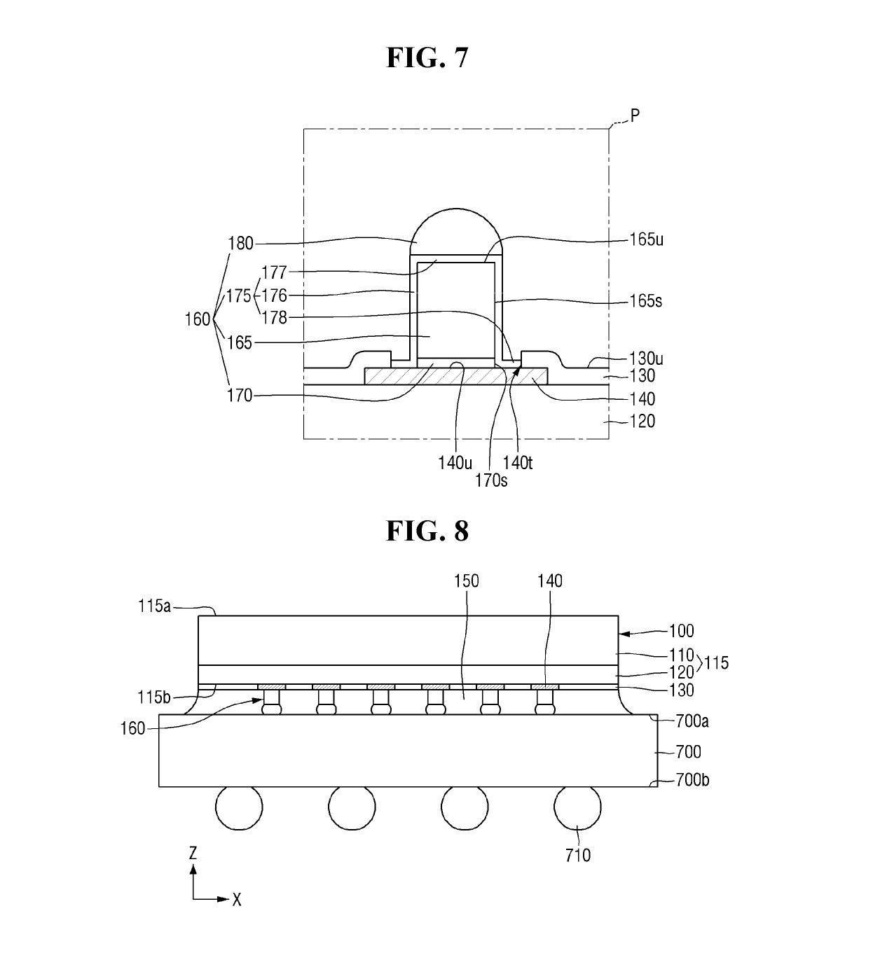

FIG. 7 is a view for explaining a semiconductor device according to still another embodiment. For convenience of explanation, differences from those described with reference to FIGS. 1 to 3 will be mainly described. For reference, FIG. 7 is an enlarged view of the portion P in FIG. 2.

Referring to FIG. 7, in the semiconductor device according to still another embodiment, the width of the first pad trench 140t may be greater than the width of the first bump structure 160. The width of the first pad trench 140t may be greater than the width of the first pillar structure 165.

The first bump structure 160 may not include a portion extending along a part of the upper surface 130u of the first passivation film 130. The first bump structure 160 may not include a portion overlapping the first passivation film 130 in the third direction Z.

The first lower metal film 170 may extend along the upper surface 140u of the first connection pad 140. However, the first lower metal film 170 may not include a portion extending along the upper surface 130u of the first passivation film 130. The first pillar structure 165 may not cover the first passivation film 130. The lower metal film 170 may have a same width as that of the first pillar structure 165.

The first metal protection film 175 may include a third portion 178 extending along the upper surface 140u of the first connection pad 140. The third portion 178 of the first metal protection film 175 is connected to the first portion 176 of the first metal protection film 175.

FIG. 8 is a view for explaining a semiconductor package according to an example embodiment.

The semiconductor package to be described below may include the semiconductor device described with reference to FIGS. 1 to 7. For convenience of explanation, descriptions of the semiconductor device including the first semiconductor chip 100 and the first bump structure 160 will be simplified or omitted.

Referring to FIG. 8, a semiconductor package according to an embodiment may include a first semiconductor chip 100, first bump structures 160, and a mounting substrate 700.

The mounting substrate 700 may be a package substrate, for example, a printed circuit board (PCB) or a ceramic substrate. The mounting substrate 700 may serve as a support substrate of a semiconductor package. The mounting substrate 700 may include a first surface 700a and a second surface 700b, facing away from each other.

First connection terminals 710 may be disposed on the second surface 700b of the mounting substrate 700. The first connection terminals 710 may electrically connect the semiconductor package to an external device. The first connection terminals 710 may provide an electrical signal to the first semiconductor chip 100 or may provide an electrical signal to the external device from the first semiconductor chip 100.

As used herein, items described as being “electrically connected” are configured such that an electrical signal can be passed from one item to the other. Therefore, a passive electrically conductive component (e.g., a wire, pad, internal electrical line, etc.) physically connected to a passive electrically insulative component (e.g., a prepreg layer of a printed circuit board, an electrically insulative adhesive connecting two devices, an electrically insulative underfill or mold layer, etc.) is not electrically connected to that component. Moreover, items that are “directly electrically connected,” to each other are electrically connected through one or more passive elements, such as, for example, wires, pads, internal electrical lines, through vias, etc.

The first semiconductor chip 100 may be disposed over the first surface 700a of the mounting substrate 700. The first semiconductor chip 100 may be connected to the mounting substrate 700.

The first bump structures 160 may be disposed between the first semiconductor chip 100 and the mounting substrate 700. The first bump structures 160 may connect the first semiconductor chip 100 with the mounting substrate 700.

A first inter-chip molding material 150 may be disposed between the first semiconductor chip 100 and the mounting substrate 700. The first inter-chip molding material 150 may cover the first bump structures 160.

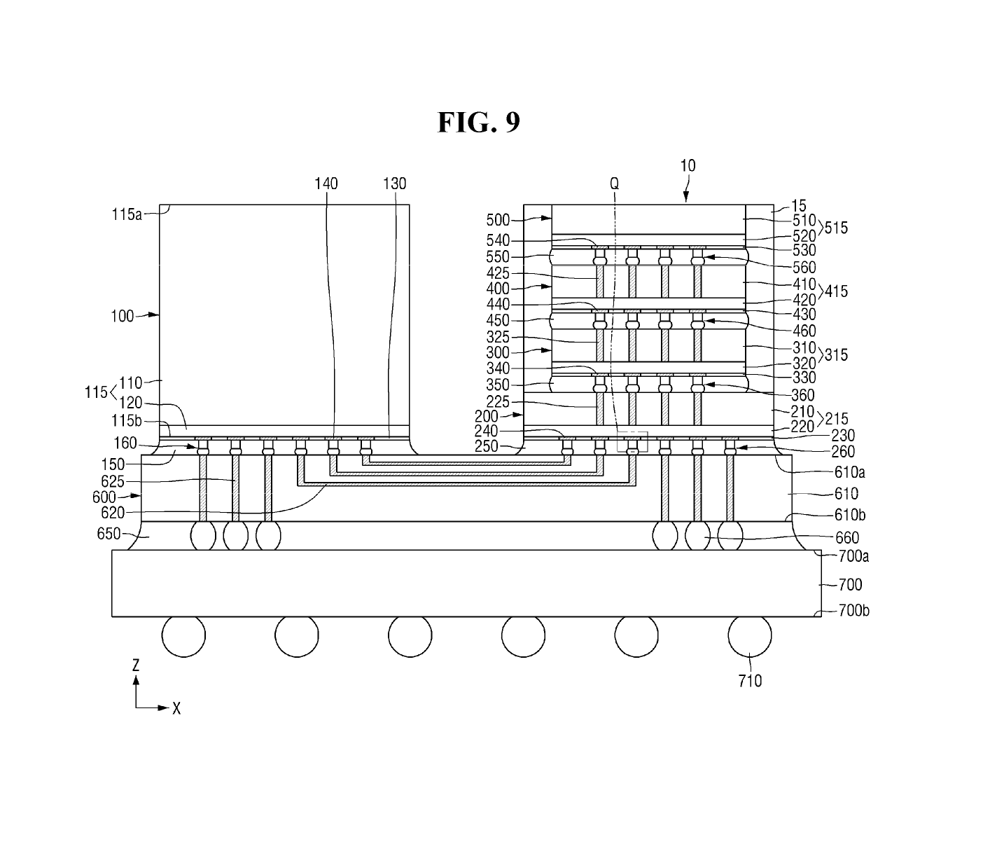

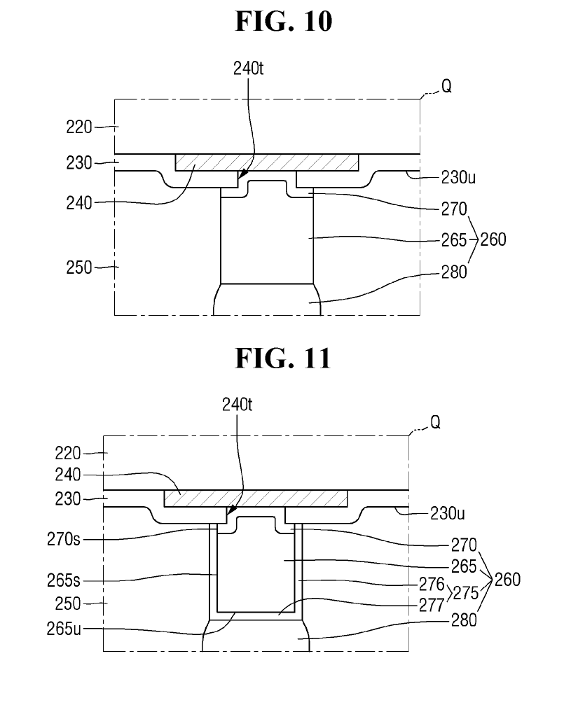

FIG. 9 is a view for explaining a semiconductor package according to another example embodiment. FIG. 10 is an enlarged view of the portion Q in FIG. 9. For convenience of explanation, differences from those described with reference to FIG. 8 will be mainly described.

Referring to FIGS. 9 and 10, a semiconductor package according to another embodiment may include a mounting substrate 700, an interposer substrate 600, a laminated chip structure 10, a first semiconductor chip 100, and first bump structures 160.

The laminated chip structure 10 may include second to fifth semiconductor chips 200, 300, 400, and 500 sequentially laminated in the third direction Z. For example, the second to fifth semiconductor chips 200, 300, 400, and 500 may be memory semiconductor chips. As another example, the second semiconductor chip 200 may be a logic semiconductor chip, and the third to fifth semiconductor chips 300, 400, and 500 may be memory semiconductor chips. The second semiconductor chip 200 may be a controller semiconductor chip for controlling the operation (for example, input and output) of the third to fifth semiconductor chips 300, 400, and 500 electrically connected to the second semiconductor chip 200.

Although it is shown in FIG. 9 that the laminated chip structure 10 includes four laminated semiconductor chips, this is only for convenience of explanation, and the present disclosure is not limited thereto.

The second semiconductor chip 200 may include a second chip substrate 215, first through vias 225, a second passivation film 230, and a second connection pad 240. The second chip substrate 215 may include a second semiconductor substrate 210 and a second semiconductor device layer 220.

The first through vias 225 may be disposed in the second chip substrate 215. The first through vias 225 may penetrate the second semiconductor substrate 210. Although it is shown in FIG. 9 that the first through vias 225 do not penetrate the second chip substrate 215 as a whole, this is only for convenience of explanation, and the present disclosure is not limited thereto. For example, in some embodiments, the first through vias 225 may penetrate the second semiconductor substrate 210 and the second semiconductor device layer 220.

The extension shape of the first through via 225 may be different depending on whether the first through via 225 is formed before a FEOL (front end of line) process, formed between a FEOL (front end of line) process and a BEOL (back end of line) process, or formed during a BEOL process or after a BEOL process.

The second connection pad 240 may be formed on the second semiconductor device layer 220. The second connection pad 240 may be electrically connected to various ones of a plurality of individual devices formed in the second semiconductor device layer 220.

The second passivation film 230 may be disposed on the second semiconductor device layer 220. The second passivation film 230 may be disposed on the second connection pad 240. The second passivation film 230 may expose a part of the second connection pad 240. The second passivation film 230 may cover at least a part of the second connection pad 240. For example, the second passivation film 230 may expose a part of the upper surface of the second connection pad 240.

The second passivation film 230 may include a second pad trench 240t exposing a part of the second connection pad 240. The second pad trench 240t may include a side wall defined by the second passivation film 230 and a bottom surface defined by the upper surface of the second connection pad 240. The side wall of the second pad trench 240t may be substantially perpendicular to the upper surface of the second connection pad 240. The second passivation film 230 may include at least one of an inorganic material film and an organic material film.

A second bump structure 260 may be disposed on the second connection pad 240. The second bump structure 260 may be connected to the second connection pad 240. For example, the second bump structure 260 may be electrically connected to and in physical contact with the second connection pad 240. The second bump structure 260 may be disposed in the second pad trench 240t. Although it is shown in FIG. 10 that the second bump structure 260 includes a portion extending along a part of the upper surface 230u of the second passivation film 230, the present disclosure is not limited thereto.

The second bump structure 260 may include a second pillar structure 265, a second lower metal film 270, and a second solder layer 280. Unlike the first bump structure 160, the second bump structure 260 may not include a metal protection film such as the first metal protection film 175.

The second pillar structure 265 may be disposed on the second connection pad 240. The second pillar structure 265 may cover a part of the second passivation film 230. The second pillar structure 265 may contain, for example, copper (Cu), copper alloy, nickel (Ni), nickel alloy, palladium (Pd), platinum (Pt), gold (Au), cobalt (Co) or a combination thereof. The second pillar structure 265 may contain the same material as the first pillar structure 165, or may contain a different material from the first pillar structure 165.

The second lower metal film 270 may be disposed between the second connection pad 240 and the second pillar structure 265. The second lower metal film 270 may extend along the side wall and bottom surface of the second pad trench 240t. A part of the second lower metal film 270 may extend along the upper surface 230u of the second passivation film 230.

The second solder layer 280 may be disposed on the second pillar structure 265. The second solder layer 280 may contain at least one of tin (Sn), indium (In), bismuth (Bi), antimony (Sb), copper (Cu), silver (Ag), zinc (Zn), lead (Pb) and/or alloys thereof. The second solder layer 280 may contain the same material as the first solder layer 180, or may contain a different material from the first solder layer 180.

The third semiconductor chip 300 may include a third chip substrate 315, second through vias 325, a third passivation film 330, and a third connection pad 340. The third chip substrate 315 may include a third semiconductor substrate 310 and a third semiconductor device layer 320. Since the third semiconductor chip 300 may have similar technical characteristics to the second semiconductor chip 200, a detailed description of the third semiconductor chip 300 will be omitted.

A third bump structure 360 may be disposed on the third connection pad 340. The third bump structure 360 may be disposed between the second semiconductor chip 200 and the third semiconductor chip 300. The third bump structure 360 may connect the second semiconductor chip 200 and the third semiconductor chip 300. Since the third bump structure 360 may have a similar structure to the second bump structure 260, a detailed description of the third bump structure 360 will be omitted.

The fourth semiconductor chip 400 may include a fourth chip substrate 415, third through vias 425, a fourth passivation film 430, and a fourth connection pad 440. The fourth chip substrate 415 may include a fourth semiconductor substrate 410 and a fourth semiconductor device layer 420. Since the fourth semiconductor chip 400 may have similar technical characteristics to the second semiconductor chip 200, a detailed description of the fourth semiconductor chip 400 will be omitted.

A fourth bump structure 460 may be disposed on the fourth connection pad 440. The fourth bump structure 460 may be disposed between the third semiconductor chip 300 and the fourth semiconductor chip 400. The fourth bump structure 460 may connect the third semiconductor chip 300 and the fourth semiconductor chip 400. Since the fourth bump structure 460 may have a similar structure to the second bump structure 260, a detailed description of the fourth bump structure 460 will be omitted.

Although it is shown in FIG. 9 that four first through vias 225, four second through vias 325, and four third through vias 425 are formed, respectively, this is only for convenience, and the present disclosure is not limited thereto. Greater or smaller numbers of first through vias 225, second through vias 325, and third through vias 425 may be formed.

The fifth semiconductor chip 500 may include a fifth chip substrate 515, a fifth passivation film 530, and a fifth connection pad 540. The fifth chip substrate 515 may include a fifth semiconductor substrate 510 and a fifth semiconductor device layer 520. Since the fifth semiconductor chip 500 may have similar technical characteristics to the second semiconductor chip 200 except for the through vias, a detailed description of the fifth semiconductor chip 500 will be omitted.

A fifth bump structure 560 may be disposed on the fifth connection pad 540. The fifth bump structure 560 may be disposed between the fourth semiconductor chip 400 and the fifth semiconductor chip 500. The fifth bump structure 560 may connect the fourth semiconductor chip 400 and the fifth semiconductor chip 500. Since the fifth bump structure 560 may have a similar structure to the second bump structure 260, a detailed description of the fifth bump structure 560 will be omitted.

A second inter-chip molding material 350 may be disposed between the second semiconductor chip 200 and the third semiconductor chip 300. The second inter-chip molding material 350 may cover the third bump structures 360. A third inter-chip molding material 450 may be disposed between the third semiconductor chip 300 and the fourth semiconductor chip 400. The third inter-chip molding material 450 may cover the fourth bump structures 460. A fourth inter-chip molding material 550 may be disposed between the fourth semiconductor chip 400 and the fifth semiconductor chip 500. The fourth inter-chip molding material 550 may cover the fifth bump structures 560.

A package molding material 15 may be disposed on the second semiconductor chip 200. The package molding material 15 may cover the respective side walls of the third to fifth semiconductor chips 300, 400 and 500. A top surface of the package molding material 15 may be at a same vertical level as that of the fifth semiconductor chip 500.

The interposer substrate 600 may include a sixth chip substrate 610, an inter-chip connection wiring 620, and fourth through vias 625. The interposer substrate 600 may serve as a support substrate of a semiconductor package.

The sixth chip substrate 610 may include a first surface 610a and a second surface 610b, facing away from each other. The sixth chip substrate 610 may contain a semiconductor material. The inter-chip connection wiring 620 and the fourth through vias 625 may be formed in the sixth chip substrate 610. Although it is shown in FIG. 9 that the fourth through vias 625 are formed to penetrate the sixth chip substrate 610, this is only for convenience of explanation, and the present disclosure is not limited thereto.

The laminated chip structure 10 and the first semiconductor chip 100 may be connected to the interposer substrate 600. The laminated chip structure 10 and the first semiconductor chip 100 may be disposed on the first surface 610a of the sixth chip substrate 610. The laminated chip structure 10 and the first semiconductor chip 100, which are located on the interposer substrate 600, may be spaced apart from each other in the first direction X.

On the first surface 610a of the sixth chip substrate 610, the laminated chip structure 10 and the first semiconductor chip 100 may be electrically connected to the interposer substrate 600, respectively. The first semiconductor chip 100 may be electrically connected to the inter-chip connection wiring 620 and the fourth through vias 625. The laminated chip structure 10 may be electrically connected to the inter-chip connection wiring 620 and the fourth through vias 625.

The first bump structure 160 may be disposed between the first semiconductor chip 100 and the interposer substrate 600. The first bump structure 160 may connect the first semiconductor chip 100 and the interposer substrate 600. For example, the first bump structure 160 may electrically and physically connect the first semiconductor chip 100 and the interposer substrate 600 with one another.

The second bump structure 260 may be disposed between the laminated chip structure 10 and the interposer substrate 600. The second bump structure 260 may be disposed between the second semiconductor chip 200 and the interposer substrate 600. The second bump structure 260 may connect the laminated chip structure 10 and the interposer substrate 600. For example, the second bump structure 260 may electrically and physically connect the laminated chip structure 10 and the interposer substrate 600 with one another. The second solder layer 280 may be disposed between the second pillar structure 265 and the interposer substrate 600.

The interposer substrate 600 on which the first semiconductor chip 100 and the laminated chip structure 10 are mounted may be disposed on the first surface 700a of the mounting substrate 700. The interposer substrate 600 may be connected to the mounting substrate 700.

A second connection terminal 660 may be disposed between the interposer substrate 600 and the mounting substrate 700. The second connection terminal 660 may electrically connect the interposer substrate 600 to the mounting substrate 700.

The first inter-chip molding material 150 may be disposed between the first semiconductor chip 100 and the interposer substrate 600. The first inter-chip molding material 150 may cover the first bump structure 160. The fifth inter-chip molding material 250 may be disposed between the laminated chip structure 10 and the interposer substrate 600. The fifth inter-chip molding material 250 may cover the second bump structure 260. The sixth inter-chip molding material 650 may be disposed between the interposer substrate 600 and the mounting substrate 700. The sixth inter-chip molding material 650 may cover the second connection terminal 660.

FIG. 11 is a view for explaining a semiconductor package according to still another example embodiment. For convenience of explanation, differences from those described with reference to FIGS. 9 and 10 will be mainly described. For reference, FIG. 11 is an enlarged view of the portion Q in FIG. 9.

Referring to FIG. 11, in a semiconductor package according to still another example embodiment, the second bump structure 260 may include a second metal protection film 275.

The second metal protection film 275 may be disposed on the second pillar structure 265. The second metal protection film 275 may extend along the side wall 265s of the second pillar structure 265 and the upper surface 265u of the second pillar structure 265.

The second metal protection film 275 may include a first portion 276 and a second portion 277. The first portion 276 of the second metal protection film 275 may extend along the side wall 265s of the second pillar structure 265. The second portion 277 of the second metal protection film 275 may extend along the upper surface 265u of the second pillar structure 265.

The first portion 276 of the second metal protection film 275 may extend along the entire side wall 265s of the second pillar structure 265. The first portion 276 of the second metal protection film 275 may extend along the side wall 270s of the second lower metal film 270. The first portion 276 of the second metal protection film 275 may cover the entire side wall 265s of the second pillar structure and the entire side wall 270s of the second lower metal film 270. The side wall 265s of the second pillar structure 265 and the side wall 270s of the second lower metal film 270 may be aligned with one another in the third direction Z.

The second metal protection film 275 may contain at least one of nickel (Ni), cobalt (Co), platinum (Pt), silver (Ag), gold (Au), and aluminum (Al). In the following description, it is assumed that the second metal protection film 275 contains nickel (Ni).

In FIGS. 9 and 10, although it has been described that each of the second to fifth bump structures 260, 360, 460, and 560 has a different structure from the first bump structure 160, the present disclosure is not limited thereto. For example, one or more of the second to fifth bump structures 260, 360, 460, and 560 may have a structure that is the same as that of the first bump structure 160.

Further, in the description with reference to FIG. 11, although it has been described that the second to fifth bump structures 260, 360, 460, and 560 includes metal protection films such as the first metal protection films 175, the present disclosure is not limited thereto.

For example, some of the second to fifth bump structures 260, 360, 460, and 560 include metal protection films such as the first metal protection films 175 of the first bump structure 160, and the remainder thereof may not include metal protection films such as the first metal protection films 175.

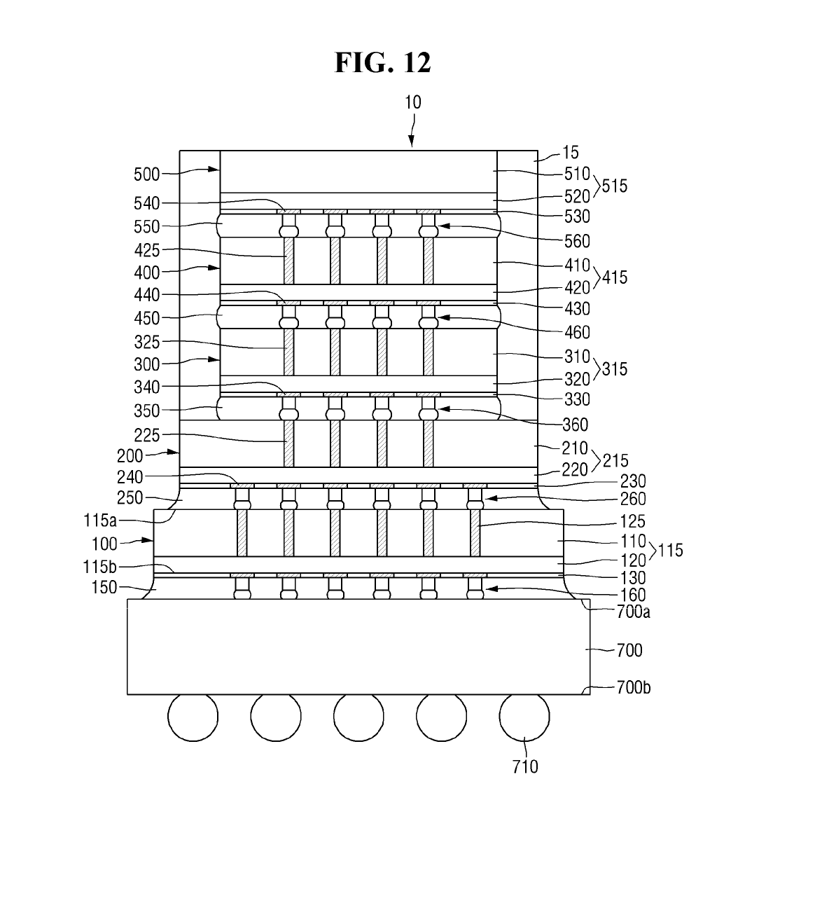

FIG. 12 is a view for explaining a semiconductor package according to still another example embodiment. For convenience of explanation, differences from those described with reference to FIG. 8 will be mainly described.

Referring to FIG. 12, a semiconductor package according to some example embodiments may include a first semiconductor chip 100, a laminated chip structure 10, and a mounting substrate 700.

The laminated chip structure 10 may be disposed on the first semiconductor chip 100. The laminated chip structure 10 may be disposed on the first surface 115a of the first chip substrate 115. Since a description of the laminated chip structure 10 is substantially the same as that having been described with reference to FIG. 9, it will be omitted.

The first semiconductor chip 100 may further include fifth through vias 125 disposed in the first chip substrate 115. The fifth through vias 125 may penetrate the first semiconductor substrate 110, extending from the first surface 115a of the first chip substrate 115 to a top surface of the first semiconductor device layer 120. The second bump structure 260 may be connected to the fifth through via 125.

The fifth inter-chip molding material 250 may be disposed between the first semiconductor chip 100 and the laminated chip structure 10. The fifth inter-chip molding material 250 may cover the second bump structure 260.

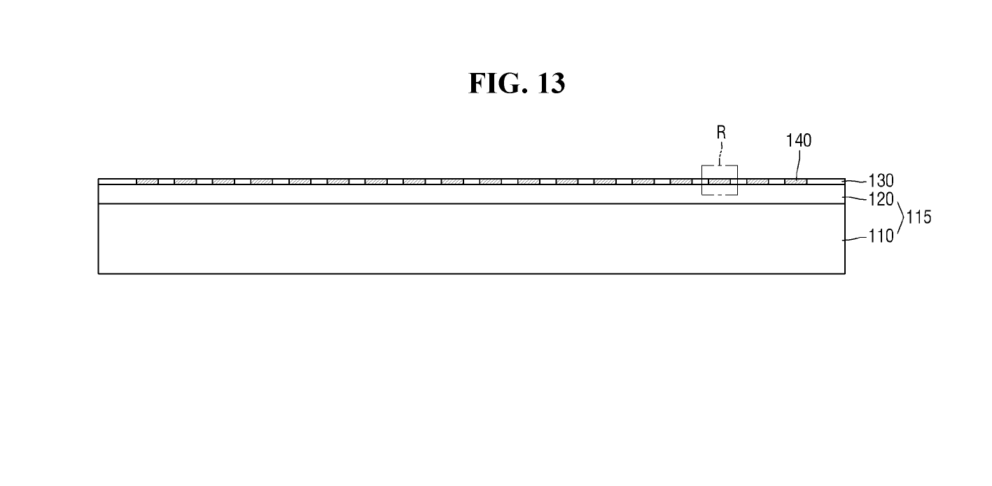

FIGS. 13 to 24 are intermediate views for explaining a method of a manufacturing a semiconductor device according to an example embodiment. FIGS. 13 to 24 may be intermediate views for explaining a method of a manufacturing the semiconductor device described with reference to FIGS. 1 to 3.

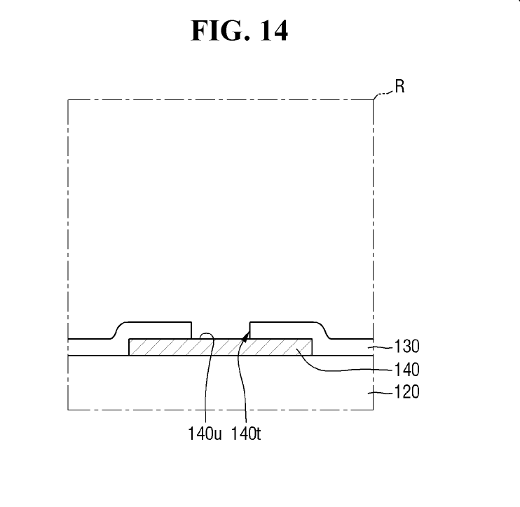

For reference, FIGS. 14 to 24 are enlarged views of the portion R in FIG. 13.

Referring to FIGS. 13 and 14, a first semiconductor device layer 120 may be formed on a first semiconductor substrate 110. A first chip substrate 115 including the first semiconductor substrate 110 and the first semiconductor device layer 120 may be formed.

The first semiconductor substrate 110 of FIG. 13 may be a semiconductor wafer prior to a substrate cutting operation for making a semiconductor chip.

A first connection pad 140 may be formed on the first semiconductor device layer 120. A first passivation film 130 exposing a part of the first connection pad 140 may be formed on the first semiconductor device layer 120. The first passivation film 130 may include a first pad trench 140t exposing a part of the upper surface 140u of the first connection pad 140. For example, the first connection pad 140 may be deposited on the first semiconductor device layer 120, and the first passivation film 130 may be deposited on the first connection pad 140. In some embodiments, the first pad trench 140t may be formed by an etching process performed on the first passivation film 130 using a mask (not illustrated).

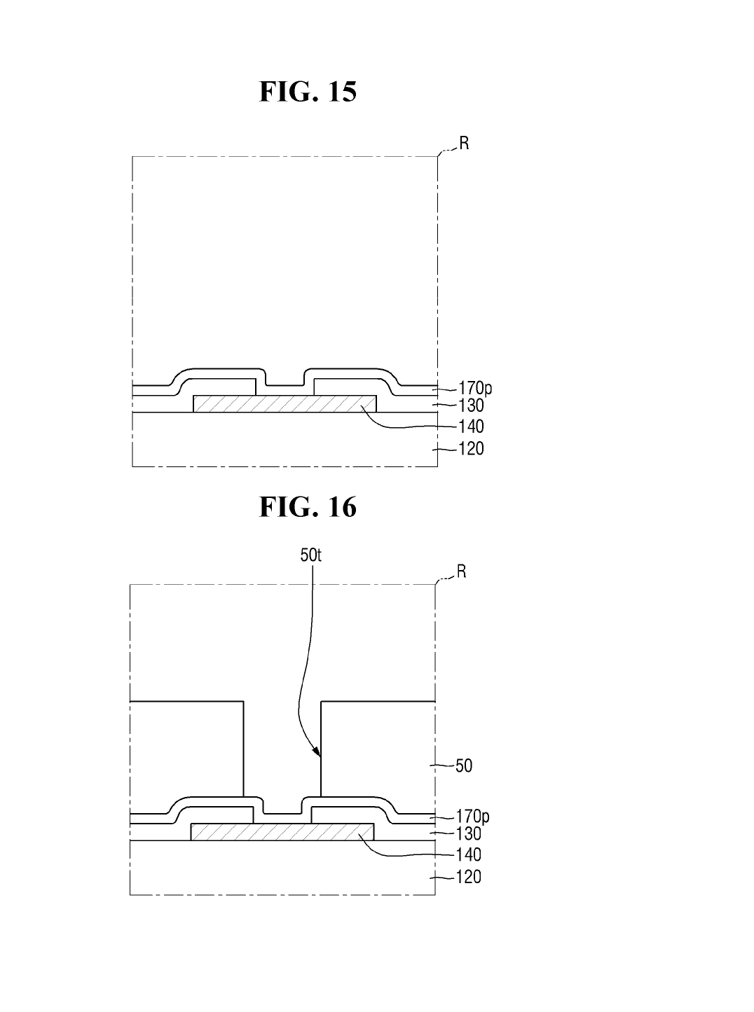

Referring to FIG. 15, a preliminary lower metal film 170p may be formed on the side wall and bottom surface of the first pad trench 140t and on the first passivation film 130.

The preliminary lower metal film 170p may be formed using a sputtering process, but the present disclosure is not limited thereto.

Referring to FIG. 16, a first mask film 50 may be formed on the preliminary lower metal film 170p.

The first mask film 50 may include a first opening trench 50t. The first opening trench 50t may expose a part of the preliminary lower metal film 170p. The first opening trench 50t may be formed to overlap with the first connection pad 140 in the third direction Z.

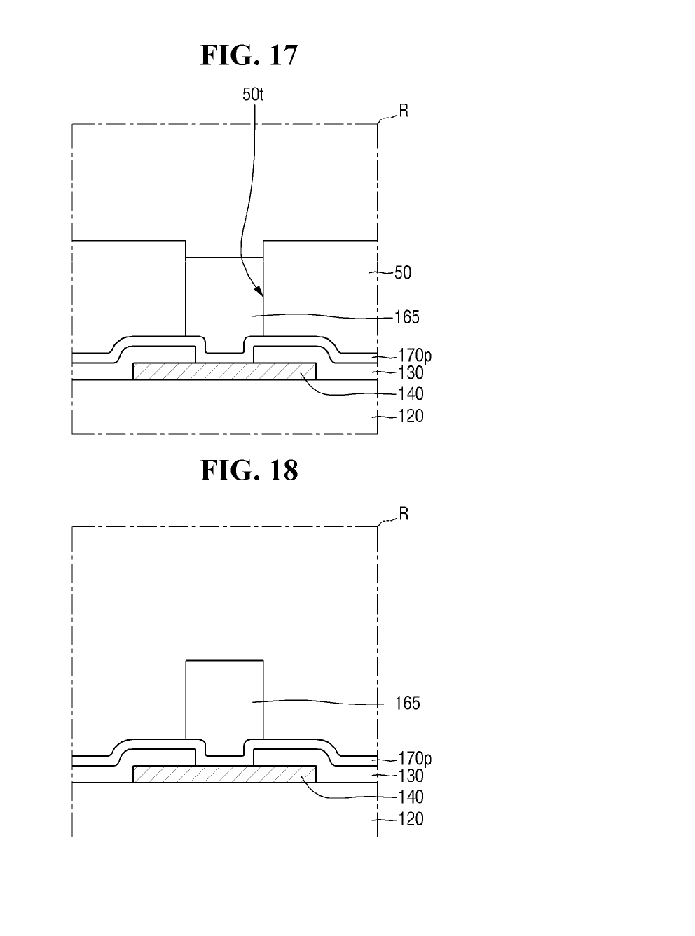

Referring to FIG. 17, a first pillar structure 165 connected to the first connection pad 140 may be formed in the first opening trench 50t.

The first pillar structure 165 may fill at least a part of the first opening trench 50t. The first pillar structure 165 may be formed using, for example, a plating process.

Referring to FIG. 18, the first mask film 50 may be removed to expose the preliminary lower metal film 170p.

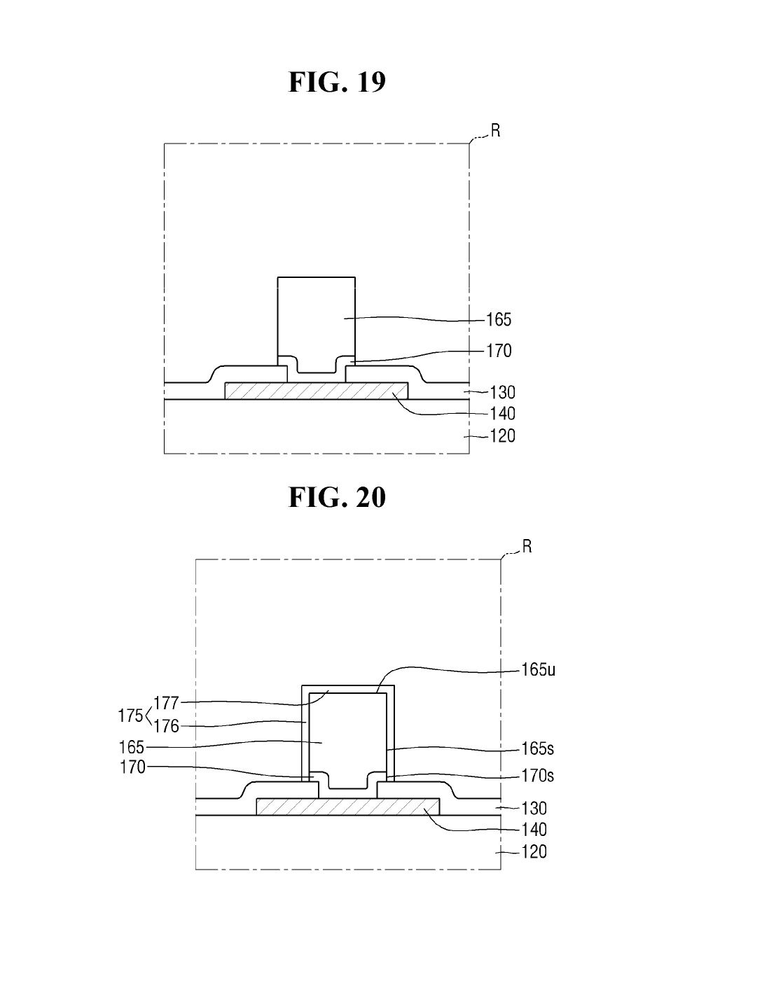

Referring to FIG. 19, the preliminary lower metal film 170p that does not overlap the first pillar structure 165 may be removed.

For example, a first lower metal film 170 may be formed between the first pillar structure 165 and the first connection pad 140.

Referring to FIG. 20, a first metal protection film 175 may be formed along the side wall 165s of the first pillar structure 165 and the upper surface 165u of the first pillar structure 165. The first metal protection film 175 may include a first portion 176 extending along the side wall 165s of the first pillar structure 165 and a second portion 177 extending along an upper surface 165u of the first pillar structure 165.

The first metal protection film 175 may also be formed on the side wall 170s of the first lower metal film 170, extending to a top surface of the first passivation film 130. The first metal protection film 175 is formed on the first pillar structure 165 and the first lower metal film 170, which contains a conductive material, but is not formed on the first passivation film 130, which contains an insulating material.

The first metal protection film 175 may be formed using, for example, an electroless plating process. The first metal protection film 175 having a uniform thickness can be formed by using the electroless plating process. The thickness of the first metal protection film 175 can be easily adjusted by adjusting the time of the electroless plating process.

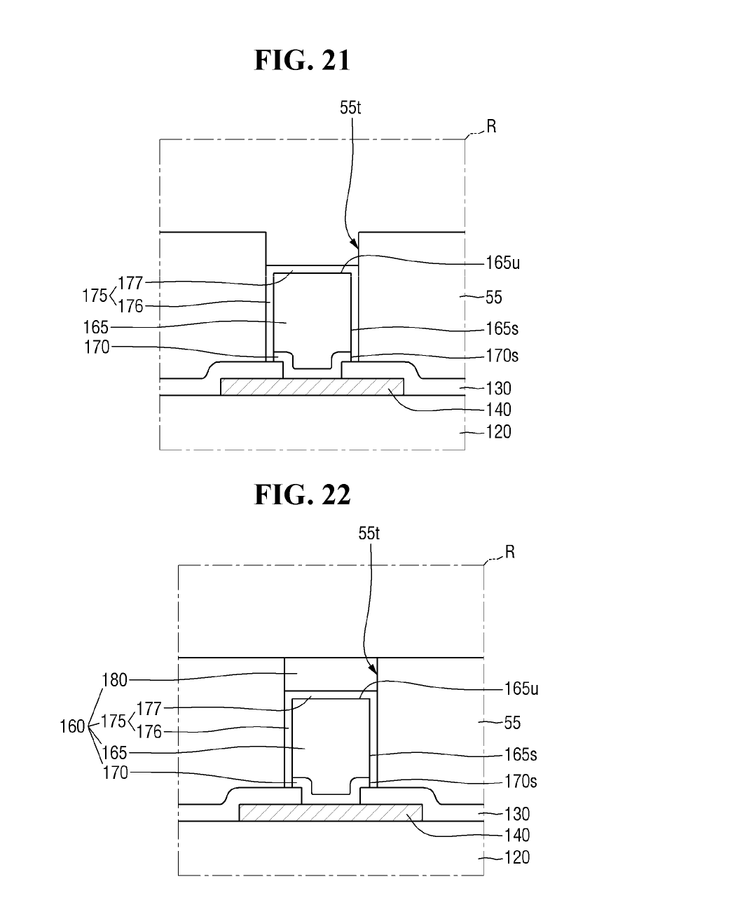

Referring to FIG. 21, a second mask film 55 exposing the first metal protection film 175 may be formed on the first passivation film 130.

The second mask film 55 may include a second opening trench 55t. The second opening trench 55t may expose at least a part of the second portion 177 of the first metal protection film 175. The sidewalls of the second opening trench 55t may be adjacent to sidewalls of the first portion 176 of the first metal protection film 175.

Referring to FIG. 22, a first solder layer 180 may be formed in the second opening trench 55t.

The first solder layer 180 may be formed on the first metal protection film 175. For example, the first solder layer 180 may be formed on the second portion 177 of the first metal protection film 175. The first solder layer 180 may fill at least a part of the second opening trench 55t.

Accordingly, a first bump structure 160 connected to the first connection pad 140 may be formed on the first connection pad 140.

The first solder layer 180 may be formed using, for example, a plating process.

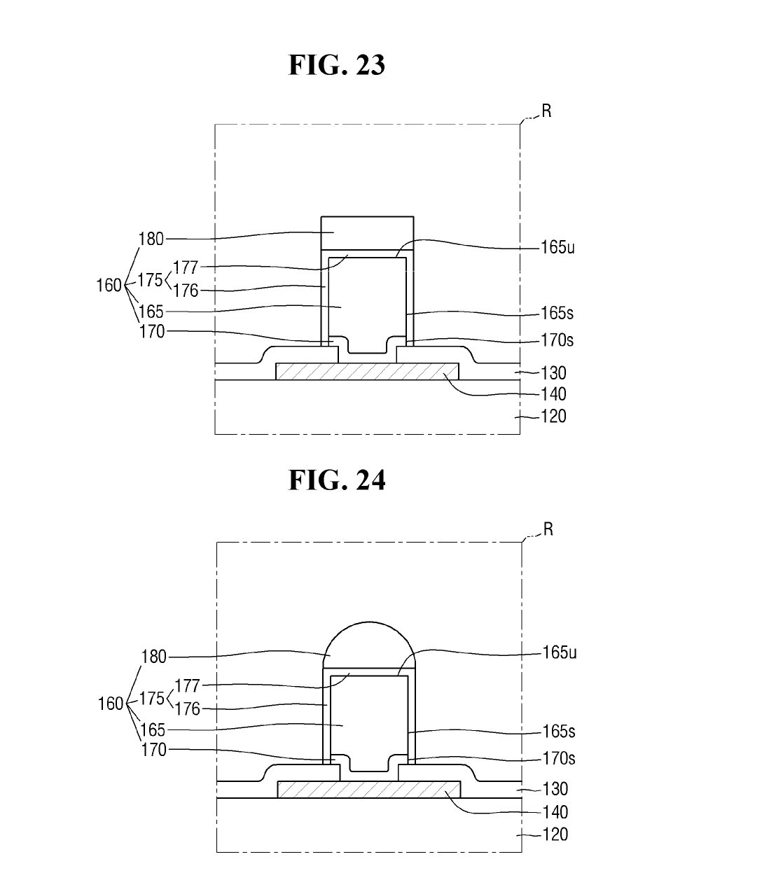

Referring to FIG. 23, the second mask film 55 may be removed to expose the first passivation film 130.

Referring to FIG. 24, the shape of the first solder layer 180 may be adjusted through a reflow process.

During the reflow process, a part of the first metal protection film 175 on the upper surface 165u of the first pillar structure 165 may enter the first solder layer 180. The amount of first metal protection film 175 that enters the first solder layer 180 may correspond to a thickness of the first portion 176 of the first metal protection film 175. For example, when the amount of the first metal protection film 175 entering the first solder layer 180 on the upper surface 165u of the first pillar structure is relatively small or little, the thickness of the first portion 176 of the first metal protection film 175 may be substantially equal to the thickness of the second portion 177 of the first metal protection film 175. When the amount of the first metal protection film 175 entering the first solder layer 180 on the upper surface 165u of the first pillar structure is relatively large, the thickness of the first portion 176 of the first metal protection film 175 may be substantially smaller than the thickness of the second portion 177 of the first metal protection film 175.

As another example, when the first metal protection film 175 on the upper surface 165u of the first pillar structure 165 enters the first solder layer 180, as shown in FIG. 4, the thickness of the second portion 177 of the first metal protection film 175 may be less than the thickness of the first portion 176 of the first metal protection film 175.

As still another example, when the thickness of the first metal protection film 175 decreases by reducing the time of an electroless plating process, the entire second portion 177 of the first metal protection film 175 may enter the first solder layer 180.

The various pads described herein may be connected to internal circuitry within the device to which they are connected, and may transmit signals and/or voltage to and/or from the device to which they are attached. For example, substrate pads disposed on the package substrate may connect to rerouting and other electrical lines disposed within the package substrate, and the pads disposed on the semiconductor chips may connect to an integrated circuit on one or more of the semiconductor chips. The various pads described herein may generally have a planar surface at a location for connecting to a terminal for external communications outside of the device to which the pads are connected. The pads may be formed of a conductive material, such a metal, for example.

While the invention has been particularly shown and described with reference to exemplary embodiments thereof, it will be understood by those of ordinary skill in the art that various changes in form and details may be made therein without departing from the spirit and scope of the invention as defined by the following claims. It is therefore desired that the present embodiments be considered in all respects as illustrative and not restrictive, reference being made to the appended claims rather than the foregoing description to indicate the scope of the invention.

1. A semiconductor device, comprising:
a substrate;
a connection pad on the substrate; and
a bump structure on the connection pad,
wherein the bump structure includes:
a pillar structure having a side wall and an upper surface,
a metal protection film including a first portion extending along the side wall of the pillar structure and a second portion extending along the upper surface of the pillar structure, and
a solder layer on the second portion of the metal protection film.

2. The semiconductor device of claim 1,
wherein the first portion of the metal protection film extends along the entire side wall of the pillar structure.

3. The semiconductor device of claim 1,
wherein the bump structure further includes a lower metal film between the pillar structure and the connection pad, and
wherein the metal protection film extends along a side wall of the lower metal film.

4. The semiconductor device of claim 1,
wherein a thickness of the first portion of the metal protection film is substantially equal to a thickness of the second portion of the metal protection film.

5. The semiconductor device of claim 1,
wherein a thickness of the first portion of the metal protection film is greater than a thickness of the second portion of the metal protection film.

6. The semiconductor device of claim 1, further comprising:
a passivation film on the substrate, the passivation film including a pad trench exposing a part of the connection pad,
wherein the pillar structure covers a part of the passivation film.

7. The semiconductor device of claim 1, further comprising:
a passivation film on the substrate, the passivation film including a pad trench exposing a part of the connection pad,
wherein a width of the pad trench is smaller than a width of the pillar structure.

8. The semiconductor device of claim 7,
wherein the metal protection film includes a portion extending along the upper surface of the connection pad.

9. The semiconductor device of claim 1,
wherein, in a region of the solder layer adjacent to a boundary with the metal protection film, the solder layer includes a solid solution region containing a metal contained in the metal protection film.

10. The semiconductor device of claim 1,
wherein the pillar structure contains copper, and
wherein the metal protection film includes a nickel film.

11. A semiconductor device, comprising:
a substrate;
a connection pad on the substrate; and
a bump structure on the connection pad,
wherein the bump structure includes a pillar structure having a side wall and an upper surface, a metal protection film formed of a metal and extending along the side wall of the pillar structure, and a solder layer on the upper surface of the pillar structure,
wherein the solder layer includes a first region defined along the upper surface of the pillar structure and a second region on the first region, and both the first region and the second region include the metal contained in the metal protection film, and
wherein a concentration of the metal contained in the metal protection film in the first region of the solder layer is a first concentration, and a concentration of the metal contained in the metal protection film in the second region of the solder layer is a second concentration lower than the first concentration.

12. The semiconductor device of claim 11,
wherein the metal protection film extends along the entire side wall of the pillar structure.

13. The semiconductor device of claim 11,
wherein the metal protection film includes a first portion extending along the side wall of the pillar structure, and a second portion disposed between the solder layer and the upper surface of the pillar structure.

14. The semiconductor device of claim 13,
wherein a thickness of the first portion of the metal protection film is substantially equal to a thickness of the second portion of the metal protection film.

15. The semiconductor device of claim 13,
wherein a thickness of the first portion of the metal protection film is greater than a thickness of the second portion of the metal protection film.

16. The semiconductor device of claim 11,
wherein the pillar structure is in contact with the solder layer.

17. (canceled)

18. A semiconductor device, comprising:
a substrate;
a connection pad on the substrate;
a passivation film including a pad trench exposing a part of the connection pad on the substrate;
a lower metal film extending along a side wall and bottom surface of the pad trench; and
a bump structure on the lower metal film,
wherein the bump structure includes:
a pillar structure containing copper (Cu),
a metal protection film extending along a side wall of the lower metal film, a side wall of the pillar structure, and an upper surface of the pillar structure, the metal protection film containing nickel, and
a solder layer on the metal protection film.

19. The semiconductor device of claim 18,
wherein a thickness of the metal protection film on the side wall of the pillar structure is substantially equal to a thickness of the metal protection film on the upper surface of the pillar structure.

20. The semiconductor device of claim 18,
wherein a thickness of the metal protection film on the side wall of the pillar structure is greater than a thickness of the metal protection film on the upper surface of the pillar structure.

21. The semiconductor device of claim 18,
wherein the solder layer includes a solid solution region containing nickel, and
the solid solution region is defined along the upper surface of the pillar structure.

22.-31. (canceled)
